(19) United States
(12) Patent Application Publication
(10) Pub. No.: US 2014/0159256 A1
(43) Pub. Date: Jun. 12, 2014

(54) ANISOTROPIC CONDUCTIVE FILMS AND SEMICONDUCTOR DEVICES CONNECTED BY THE SAME

(71) Applicants: Hyun Min CHOI, Uiwang-si (KR); Young Woo PARK, Uiwang-si (KR)

(72) Inventors: Hyun Min CHOI, Uiwang-si (KR); Young Woo PARK, Uiwang-si (KR)

(21) Appl. No.: 14/070,660

(22) Filed: Nov. 4, 2013

(30) Foreign Application Priority Data
Dec. 7, 2012 (KR) 10-2012-0141660

(51) Int. Cl. H01L 23/00

(52) U.S. Cl. CPC H01L 24/29; H01L 24/83
USPC 257/783; 428/343; 428/337; 438/119

(57) ABSTRACT

An anisotropic conductive film, a method for preparing a semiconductor device, and a semiconductor device, the anisotropic conductive film including a base film, the base film having a storage modulus of 5,000 kgf/cm² or less or a coefficient of thermal expansion of 50 ppm/° C. or less at 100° C. to 150° C.; and an adhesive layer on the base film, the adhesive layer containing conductive particles.

### CROSS-REFERENCE TO RELATED APPLICATION

Korean Patent Application No. 10-2012-0141660, filed on Dec. 7, 2012, in the Korean Intellectual Property Office, and entitled: “Semiconductor Devices Connected By Anisotropic Conductive Film,” is incorporated by reference herein in its entirety.

### BACKGROUND

1. Field

Embodiments relate to a semiconductor device connected by an anisotropic conductive film.

2. Description of the Related Art

With the recent trend toward large and thin displays, a pitch between electrodes and circuits may be precise or small, and an anisotropic conductive film (ACF) may perform a very important role as a wiring material to connect fine circuit terminals.

### SUMMARY

Embodiments are directed to a semiconductor device connected by an anisotropic conductive film.

The embodiments may be realized by providing an anisotropic conductive film including a base film, the base film having a storage modulus of 5,000 kgf/cm² or less or a coefficient of thermal expansion of 50 ppm/° C. or less at 100° C. to 150° C.; and an adhesive layer on the base film, the adhesive layer containing conductive particles.

The base film may include a silicone polymer, polyethylene, or styrene-ethylene/propylene-styrene (SEPS) block copolymer film.

The anisotropic conductive film may have a pre-compression temperature from 30° C. to 100° C.

The base film may have a thickness from 10 μm to 250 μm.

The embodiments may also be realized by providing a method for preparing a semiconductor device, the method including disposing an anisotropic conductive film on an interconnection substrate, wherein the anisotropic conductive film includes a base film having a storage modulus of 5,000 kgf/cm² or less or a coefficient of thermal expansion of 50 ppm/° C. or less at 100° C. to 150° C.; and an adhesive layer on the base film, the adhesive layer containing conductive particles, and wherein the interconnection substrate includes metal or metal oxide layers in an outermost layer thereof; preliminarily compressing the anisotropic conductive film on the interconnection substrate by bringing a pre-compression device into direct contact with the anisotropic conductive film for pre-compression; removing the base film from the anisotropic conductive film; and mounting a semiconductor chip on the anisotropic conductive film after removing the base film, and primarily compressing the semiconductor chip thereon.

The pre-compression device may be brought into direct contact with the base film of the anisotropic conductive film upon pre-compression.

The base film may be a silicone polymer, polyethylene, or styrene-ethylene/propylene-styrene (SEPS) block copolymer film.

The base film may have a thickness from 10 μm to 250 μm.

The embodiments may also be realized by providing a semiconductor device prepared according to the method according to an embodiment.

### BRIEF DESCRIPTION OF DRAWINGS

Features will be apparent to those of skill in the art by describing in detail exemplary embodiments with reference to the attached drawings in which:

FIG. 1 illustrates a stage in a process in which an anisotropic conductive film (including an adhesive layer and a base film) according to an embodiment is disposed on an interconnection substrate and is preliminarily compressed thereto through a pre-compression header; and

FIG. 2 illustrates a side sectional view of a semiconductor device in which a semiconductor chip is disposed on the adhesive layer for a primary compression process after the pre-compression process, with a base film removed from the anisotropic conductive film.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

According to an embodiment, a semiconductor device may include an interconnection substrate subjected to pre-compression through an anisotropic conductive film. The anisotropic conductive film may include a base film (satisfying at least one condition of or having a storage modulus of 5,000 kgf/cm² or less or a coefficient of thermal expansion of 50 ppm/° C. or less at 100° C. to 150° C.) and an adhesive layer on the base film and containing conductive particles. In an implementation, the base film may have a storage modulus of 3,000 kgf/cm² or less and/or a coefficient of thermal expansion of 5 ppm/° C. to 30 ppm/° C., e.g., a storage modulus of 100 kgf/cm² to 2,000 kgf/cm² and/or a coefficient of thermal expansion of 5 ppm/° C. to 20 ppm/° C. Herein, the coefficient of thermal expansion refers to an absolute value thereof, e.g., the base film according to an embodiment expands or shrinks at 50 ppm/° C. or less at 100° C. to 150° C.

With the base film having a storage modulus of 5,000 kgf/cm² or less, the anisotropic conductive film may have high elasticity and may uniformly distribute pressure upon pre-compression, thereby improving wettability and pre-compression properties. In addition, with improved wettability, the anisotropic conductive film facilitates pre-compression even at a low pre-compression temperature, e.g., of about 30° C., without undesirable lifting, bubbles, and ACF edge overflow. Thus, according to an embodiment, the anisotropic conductive film may have a pre-compression temperature from 30° C. to 100° C. In an implementation, the anisotropic conductive film may have a pre-compression temperature from 40° C. to 100° C. As used herein, the expression “pre-compression temperature” means that a failure rate of lifting, occurrence of bubbles, and/or occurrence of an edge overflow is 5% or less, e.g., 1% or less or 0.1% or less, when observing for the occurrence of lifting, bubbles, and edge overflow through a microscope after pre-compression at the corresponding temperature and at 1 MPa for 1 second. The pre-compression temperature may be determined based on a softening point of an adhesive composition in order to secure wetting uniformity of the composition. According to an embodiment, the film may have improved wettability by increasing elasticity of the base film and pre-compression is possible even at a low temperature of the softening point or less, regardless of types of the compositions.

In addition, the use of the base film having a coefficient of thermal expansion of 50 ppm/° C. or less at 100° C. to 150° C. may help reduce and/or prevent overflow of the adhesive layer on a film edge. Such a phenomenon may otherwise occur in a base film having high thermal shrinkage. The base film having a coefficient of thermal expansion of 50 ppm/° C. or less at 100° C. to 150° C. may provide uniform pressure distribution, thereby improving wettability.

Examples of the base film may include silicone polymers, polyethylene, and styrene-ethylene/propylene-styrene (SEPS) block copolymers. In an implementation, the base film may employ a silicone polymer.

The conductive particle-containing adhesive layer may be prepared from an adhesive composition prepared by dispersing conductive particles (e.g., metallic particles or the like) in an insulating resin (e.g., epoxy, urethane and/or acrylic resins, or the like). The conductive particle-containing adhesive layer or adhesive composition may include other components, e.g., binder resins, radical polymerization materials, radical polymerization initiators, coupling agents, or the like.

The base film may have a thickness of 10 μm to 250 μm. In an implementation, the base film may have a thickness from 10 μm to 200 μm, e.g., from 10 μm to 150 μm.

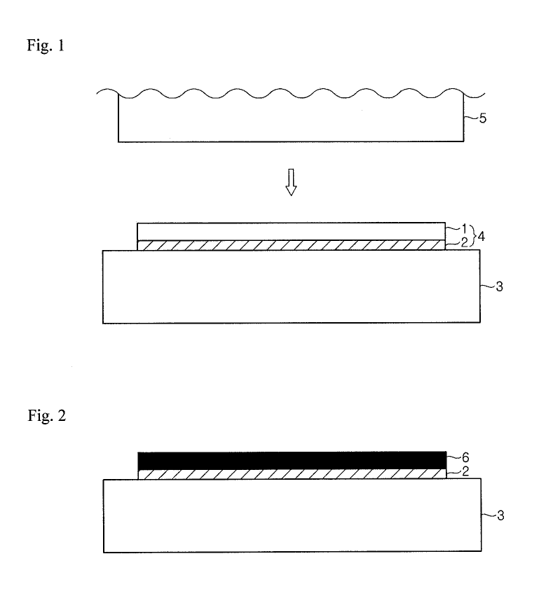

Referring to FIG. 1, according to an embodiment, a method for preparing a semiconductor device may include: disposing an anisotropic conductive film 4, which includes a base film 1 (having a storage modulus of 5,000 kgf/cm² or less or a coefficient of thermal expansion of 50 ppm/° C. or less at 100° C. to 150° C.) and an adhesive layer 2 on the base film 1 and containing conductive particles, on an interconnection substrate 3 (including metal or metal oxide layers in outermost layer thereof); and preliminarily compressing the anisotropic conductive film 4 on the interconnection substrate 3 by bringing a pre-compression device 5 into direct contact with the anisotropic conductive film 4 upon pre-compression. Herein, direct contact means that the pre-compression device 5 is brought into contact with the anisotropic conductive film 4 without a buffer sheet such as a silicone sheet. Referring to FIG. 2, after pre-compression, the method may further include: removing the base film 1 from the anisotropic conductive film 4; and mounting a semiconductor chip 6 on the adhesive layer 2. After mounting the semiconductor chip 6 on the adhesive layer 2, the method may further include: primarily compressing the semiconductor chip 6 on the adhesive layer 2.

Another embodiment relates to a method for manufacturing a semiconductor device. The method may include the following steps.

I) Disposing an anisotropic conductive film on an interconnection substrate. The anisotropic conductive film may include, e.g., a base film satisfying at least one condition of or having a storage modulus of 5,000 kgf/cm² or less or a coefficient of thermal expansion of 50 ppm/° C. or less at 100° C. to 150° C.; and an adhesive layer on the base film and containing conductive particles. The interconnection substrate may include metal or metal oxide layers in an outermost layer thereof.

II) Preliminarily compressing the anisotropic conductive film on the interconnection substrate by bringing a pre-compression device into direct contact with the anisotropic conductive film for pre-compression.

III) Removing the base film from the anisotropic conductive film.

IV) Mounting a semiconductor chip on the anisotropic conductive film (from which the base film has been removed), and primarily compressing the semiconductor chip thereon.

In the above embodiment, the anisotropic conductive film may be prepared by forming the conductive particle-containing adhesive layer on the base film having a storage modulus of 5,000 kgf/cm² or less or a coefficient of thermal expansion of 50 ppm/° C. or less at 100° C. to 150° C. In an implementation, the anisotropic conductive film according to an embodiment may be prepared by a method in which an adhesive layer containing conductive particles is formed on a polyethylene terephthalate (PET) base film, and then transferred to the base film having a storage modulus of 5,000 kgf/cm² or less or a coefficient of thermal expansion of 50 ppm/° C. or less at 100° C. to 150° C.

The embodiments also relate to a semiconductor device. The semiconductor device may include, e.g., a) an interconnection substrate including metal or metal oxide layers in an outermost layer thereof; b) an adhesive layer attached to a chip mounting surface of the interconnection substrate and formed from an anisotropic conductive film according to an embodiment by removing the base film of the anisotropic conductive film; and c) a semiconductor chip mounted on the adhesive layer.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1

### Preparation of Anisotropic Conductive Film

Based on parts by weight of solid content of the following components, 10 parts by weight of a butadiene resin, 30 parts by weight of an acrylate-modified urethane resin, 20 parts by weight of an acrylic copolymer, 36 parts by weight of a radical polymerization material, 2 parts by weight of an organic peroxide, and 2 parts by weight of conductive particles were mixed, dissolved, and dispersed using a planetary mixer. Then, the mixture was coated onto a peel-treated 250 μm thick silicone polymer film (storage modulus: 668 kgf/cm²), and dried in a hot air circulation oven at 60° C. for 5 minutes to dry solvents, thereby preparing an anisotropic conductive film of Example 1.

1. Butadiene resin: Acrylonitrile butadiene copolymer (1072CGX, Zeon Chemical Co., Ltd.) dissolved in toluene/methylethylketone to 25 vol % (% by volume)

2. Acrylate-modified urethane resin: Polyurethane acrylate (weight average molecular weight: 25,000 g/mol) prepared by polyaddition polymerization using dibutyltindilaurylate as a catalyst under conditions of 60 vol % of a polyol and a mole ratio of hydroxyl methacrylate/isocyanate of 0.5 dissolved in methylethylketone to 50 vol % at 90° C. and 1 atm for 5 hours

3. Acrylic copolymer: Acrylic resin (AOF7003, Aekyung Chemical Co., Ltd.) having a weight average molecular weight from 90,000 g/mol to 120,000 g/mol dissolved in toluene/methylethylketone to 40 vol %

4. Radical polymerizable material: Epoxy acrylate polymer (SP1509, Showa Polymer Co., Ltd.)

5. Organic peroxide: Benzoyl peroxide

6. Conductive particles: Conductive particles (Au-coated Ni particles) having a particle size of 3 μm

### Example 2

### Preparation of Anisotropic Conductive Film

An anisotropic conductive film was prepared by the same method as in Example 1 except that a 150 μm thick silicone polymer film (storage modulus: 659 kgf/cm²) was used.

### Example 3

### Preparation of Anisotropic Conductive Film

An anisotropic conductive film was prepared by the same method as in Example 1 except that a 50 μm thick silicone polymer film (storage modulus: 643 kgf/cm²) was used.

### Example 4

### Preparation of Anisotropic Conductive Film

An anisotropic conductive film was prepared by the same method as in Example 1 except that a 50 μm thick silicone polymer film (storage modulus: 3,000 kgf/cm²) was used.

### Example 5

### Preparation of Anisotropic Conductive Film

An anisotropic conductive film was prepared by the same method as in Example 1 except that a 50 μm thick silicone polymer film (storage modulus: 1,500 kgf/cm²) was used.

### Comparative Examples 1 to 3

### Preparation of Anisotropic Conductive Film

Anisotropic conductive films were prepared by the same method as in Example 1 except that PET release films (PET WH film, Nippa Co., Ltd.) were used as base films. In addition, a silicone sheet was applied to Comparative Example 3 upon pre-compression for property evaluation.

### Experimental Example

### Property Evaluation of Anisotropic Conductive Film

Properties of the anisotropic conductive films prepared in the Examples and the Comparative Examples were evaluated, and results are shown in Table 1, below.

TABLE 1

| | | | | | | Comparative | Comparative | Comparative |
|---|---|---|---|---|---|---|---|---|
| | Example 1 | Example 2 | Example 3 | Example 4 | Example 5 | Example 1 | Example 2 | Example 3 |
| Base film | Silicone | Silicone | Silicone | Silicone | PE film | PET release | PET release | PET release |
| | polymer | polymer | polymer | polymer | | film | film | film |
| Nitto Tape Peel | 30 | 20 | 30 | 30 | 20 | 10 | 20 | 20 |
| strength | | | | | | | | |
| (gf/inch) | | | | | | | | |
| Application of | x | x | x | x | x | x | x | ∘ |
| silicone polymer | | | | | | | | |
| sheet upon pre- | | | | | | | | |
| compression | | | | | | | | |
| Heat resistance (° C.) | 400~500 | 400~500 | 400~500 | 400~500 | 150~200 | 200~250 | 200~250 | 200~250 |
| Film thickness (μm) | 250 | 150 | 50 | 50 | 50 | 50 | 20 | 50 |
| Coefficient of | 37 | 35 | 36 | 48 | 50 | −117 | −108 | −112 |
| thermal expansion | | | | | | | | |
| (ppm/° C.) | | | | | | | | |
| Storage modulus | 668 | 659 | 643 | 3,000 | 1,500 | 18,518 | 19,012 | 18,654 |
| (kgf/cm²) | | | | | | | | |
| Pre-compression | 5/5 | 5/5 | 5/5 | 2/5 | 0/5 | 0/5 | 0/5 | 0/5 |
| [30° C.] | | | | | | | | |
| Pre-compression | 5/5 | 5/5 | 5/5 | 3/5 | 0/5 | 0/5 | 0/5 | 0/5 |
| [40° C.] | | | | | | | | |
| Pre-compression | 5/5 | 5/5 | 5/5 | 4/5 | 2/5 | 0/5 | 0/5 | 0/5 |
| [50° C.] | | | | | | | | |
| Pre-compression | 5/5 | 5/5 | 5/5 | 4/5 | 3/5 | 0/5 | 0/5 | 0/5 |
| [60° C.] | | | | | | | | |
| Pre-compression | 5/5 | 5/5 | 5/5 | 5/5 | 5/5 | 5/5 | 0/5 | 0/5 |
| [70° C.] | | | | | | | | |
| Pre-compression | 5/5 | 5/5 | 5/5 | 5/5 | 5/5 | 5/5 | 5/5 | 5/5 |
| [80° C.] | | | | | | | | |
| Pre-compression | 5/5 | 5/5 | 5/5 | 5/5 | 4/5 | 5/5 | 5/5 | 5/5 |
| [90° C.] | | | | | | | | |
| Pre-compression | 5/5 | 5/5 | 5/5 | 5/5 | 4/5 | 1/5 | 3/5 | 2/5 |
| [100° C.] | | | | | | | | |
| Edge overflow | none | none | none | none | none | generation | generation | generation |
| (100° C.) | | | | | | | | |
| Bubble generation | none | none | none | none | none | generation | generation | generation |
| after pre-compression | | | | | | | | |
| at 80° C. | | | | | | | | |
| Adhesive strength | 40 | 42 | 42 | 44 | 31 | 34 | 42 | 41 |
| after primary | | | | | | | | |
| compression (MPa) | | | | | | | | |
| Adhesive strength | 41 | 42 | 41 | 42 | 32 | 37 | 42 | 42 |
| after reliability test | | | | | | | | |
| (MPa) | | | | | | | | |
| Contact resistance | 4.32 | 3.57 | 3.47 | 3.87 | 4.82 | 4.21 | 4.87 | 4.32 |
| after reliability test | | | | | | | | |
| (Ω) | | | | | | | | |

Evaluation of Properties

(1) Adhesive Strength

To evaluate circuit connection performance of the anisotropic conductive films prepared in Examples 1 to 5 and Comparative Examples 1 to 3, compression was performed using an IC (electrode height: 12 μm, Sumitomo Co., Ltd.) and a glass TEG (pattern-free bare glass TEG, Cheil Industries Inc.).

After each of the prepared anisotropic conductive films was placed on a circuit forming section of a glass panel and pre-compression was performed at 80° C. and 1 MPa for 1 second, each of the base films in Examples 1 to 5 or each of the release films in Comparative Examples 1 to 3 (in Comparative Example 3, including the silicone polymer sheet) was removed and substituted with an integrated circuit (IC), followed by primary compression at 210° C. and 50 MPa for 5 seconds. Then, force applied to a compressed region was measured when pushing a chip region in a 180° direction thereto using a die shear tester (DAGE2000). In addition, to evaluate connection reliability, after each of the circuit-connected specimens was kept under constant temperature and humidity conditions of 85° C. and 85% for 500 hours, adhesive strength thereof was measured in the same manner as in the above.

(2) Connection Resistance

Connection resistance was measured using a 2-point probe method after the specimens were subjected to preliminary and primary compression under the conditions as in (1) and was kept under constant temperature and humidity conditions for evaluation of reliability. A resistance tester was used in the 2-point probe method, and resistance between two points was measured using two probes connected to the tester. With the resistance tester, the resistance was calculated and displayed based on the voltage measured when 1 mA was applied to the specimen.

(3) Coefficient of Thermal Expansion

Coefficient of thermal expansion was measured after each of the base films or matrix films of the Examples and the Comparative Examples was mounted on a probe of a TMA (TA Instruments). Here, a temperature increasing rate was 10° C./min, and testing was performed within a temperature range from 100° C. to 150° C. The coefficient of thermal expansion was defined as an expansion length per unit temperature and per unit length, and could be calculated using a slope of a graph displayed on a tester.

(4) Storage Modulus

Storage modulus was measured by 180° peeling of each of the base films or matrix films at a speed of 5 mm/min at room temperature using a UTM. Here, a 500N JIG was used as a UTM JIG.

(5) Nitto Tape Peel Strength

A Nitto tape was pushed by a roller to be attached to each of the anisotropic conductive films prepared in Examples 1 to 5 and Comparative Examples 1 to 3. After 1 hour, a 180° peeling test was performed using a UTM.

(6) Pre-Compression Properties

After pre-compression of each of the anisotropic conductive films prepared in Examples 1 to 5 and Comparative Examples 1 to 3 to a glass TEG at temperatures from 40° C. to 100° C. and at 1 MPa for 1 second, the occurrence of lifting, bubbles, and edge overflow was observed using a microscope. Then, the number of cases that a failure rate of lifting, bubbles, or edge overflow was 0 was counted.

(7) Heat Resistance

To evaluate heat resistance, a temperature point at which an organic material was decomposed was measured by measuring the weight of each of the anisotropic conductive films prepared in Examples 1 to 5 and Comparative Examples 1 to 3 while heating the film using a thermogravimetric analyzer (TGA).

(8) Bubble Generation after Pre-Compression

After pre-compression of each of the prepared anisotropic conductive films was performed at 80° C. in the same manner as in (1), it was determined whether bubbles were generated by observing the backside of a glass sheet through a microscope.

By way of summation and review, processes using ACFs for printed circuit board (PCB)/outer lead bonding (OLB) and chip-on-glass (COG)/film-on-glass (FOG) applied to LCD and OLED module processes may include a pre-compression process (in which an ACF is cut to a constant length and mounted), and a primary compression process (in which COF, FPC and Drive IC are secured).

A failure in a pre-compression process in a mounting process may be caused by lack of margin for temperature and pressure. Examples of failures may include bubble generation due to wetting failure on a substrate, detachment failure due to excessive adhesive strength to a base film, and edge overflow of an adhesive layer on an edge of the base film, causing misalignment and compression failure in a primary compression process, reduction of adhesive strength, and connection failure due to water permeation in reliability testing.

The embodiments may help prevent bubble generation caused by wetting failure in a pre-compression process of anisotropic conductive films, detachment failure caused by excessive adhesive strength to a base film, and edge overflow of an adhesive layer on an edge of the base film.

The embodiments may provide a semiconductor device connected using an anisotropic conductive film, which may be pre-compressed due to good adhesion, even under conditions of a low pre-compression temperature of about 30° C., by improving temperature margin for pre-compression over a narrow temperature margin of other anisotropic conductive films.

A base film according to an embodiment may have a storage modulus of 5000 kgf/cm² or less or a coefficient of thermal expansion of 50 ppm/° C. or less at 100° C. to 150° C., and the anisotropic conductive film may have reduced thermal shrinkage and improved elasticity, as compared with polyethylene terephthalate (PET) films. Thus, pressure may be uniformly applied to respective bumps upon pre-compression of the anisotropic conductive film, and the anisotropic conductive film may exhibit improved pre-compression properties.

The anisotropic conductive film according to an embodiment may achieve uniform pressure distribution upon pre-compression and may exhibit improved wettability, thereby facilitating pre-compression to or on an interconnection substrate within a wide temperature range.

In addition, the anisotropic conductive film according to an embodiment may exhibit improved connection reliability by reducing and/or preventing bubble generation (caused by wetting failure on a substrate), detachment failure (caused by excessive adhesive strength to a base film), and/or overflow of an adhesive layer on an edge of the base film.

The anisotropic conductive film may achieve uniform pressure distribution when compared with using a separate silicone sheet, thereby eliminating the need for a separate silicone sheet, and may have excellent peel strength, thereby ensuring that the base film is peeled off after pre-compression.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An anisotropic conductive film, comprising:
a base film, the base film having a storage modulus of 5,000 kgf/cm² or less or a coefficient of thermal expansion of 50 ppm/° C. or less at 100° C. to 150° C.; and
an adhesive layer on the base film, the adhesive layer containing conductive particles.

2. The anisotropic conductive film as claimed in claim 1, wherein the base film includes a silicone polymer, polyethylene, or styrene-ethylene/propylene-styrene (SEPS) block copolymer film.

3. The anisotropic conductive film as claimed in claim 1, wherein the anisotropic conductive film has a pre-compression temperature from 30° C. to 100° C.

4. The anisotropic conductive film as claimed in claim 1, wherein the base film has a thickness from 10 μm to 250 μm.

5. A method for preparing a semiconductor device, the method comprising:
disposing an anisotropic conductive film on an interconnection substrate,
wherein the anisotropic conductive film includes:
a base film having a storage modulus of 5,000 kgf/cm² or less or a coefficient of thermal expansion of 50 ppm/° C. or less at 100° C. to 150° C.; and
an adhesive layer on the base film, the adhesive layer containing conductive particles, and
wherein the interconnection substrate includes metal or metal oxide layers in an outermost layer thereof;
preliminarily compressing the anisotropic conductive film on the interconnection substrate by bringing a pre-compression device into direct contact with the anisotropic conductive film for pre-compression;
removing the base film from the anisotropic conductive film; and
mounting a semiconductor chip on the anisotropic conductive film after removing the base film, and primarily compressing the semiconductor chip thereon.

6. The method as claimed in claim 5, wherein the pre-compression device is brought into direct contact with the base film of the anisotropic conductive film upon pre-compression.

7. The method as claimed in claim 5, wherein the base film is a silicone polymer, polyethylene, or styrene-ethylene/propylene-styrene (SEPS) block copolymer film.

8. The method as claimed in claim 5, wherein the base film has a thickness from 10 μm to 250 μm.

9. A semiconductor device prepared according to the method as claimed in claim 5.
